(19) United States
(12) Patent Application Publication
(10) Pub. No.: US 2024/0194743 A1
(43) Pub. Date: Jun. 13, 2024

(54) SEMICONDUCTOR WAFER AND METHOD FOR PROCESSING A SEMICONDUCTOR WAFER

(71) Applicant: Robert Bosch GmbH, Stuttgart (DE)

(72) Inventors: Bernhard Polzinger, Stuttgart (DE); Christian Foerster, Reutlingen (DE); Jens Buettner, Reutlingen (DE); Kristina Vogt, Muenchingen (DE)

(21) Appl. No.: 18/532,810

(22) Filed: Dec. 7, 2023

(30) Foreign Application Priority Data
Dec. 12, 2022 (DE) 102022213419.2

(51) Int. Cl. H01L 29/34; H01L 21/304; H01L 21/78

(52) U.S. Cl. CPC H01L 29/34; H01L 21/304; H01L 21/78

(57) ABSTRACT

A semiconductor wafer having a front side and a rear side, the front side is opposite the rear side. The front side has different mechanical stress regions. A structured carrier substrate that has different materials with different material properties is arranged on the front side, wherein the different materials are arranged on the different mechanical stress regions.

### FIELD

The present invention relates to a semiconductor wafer and to a method for processing a semiconductor wafer.

### BACKGROUND INFORMATION

To produce semiconductor chips, up to 600 individual process steps are necessary. After completion of the active front side of power semiconductor devices, the semiconductor wafers have intrinsic tensile stresses and compressive stresses that are generated by the application of different materials in different thicknesses and by the structuring of the semiconductor wafer with a plurality of trenches in a preferred direction. Such stresses result in an uncontrollable wafer bow and make further processing of the semiconductor wafer more difficult or even impossible the thinner the wafers become.

An object of the present invention is to overcome these disadvantages.

### SUMMARY

A semiconductor wafer has a front side and a rear side, wherein the front side is opposite the rear side and the front side has different mechanical stress regions. According to an example embodiment of the present invention, a structured carrier substrate that has different materials with different material properties is arranged on the front side, wherein the different materials are arranged on the different mechanical stress regions.

An advantage here is that mechanical stress regions on the semiconductor wafer are locally compensated for, so that further processing is reliably possible as a result of reduced distortions and curvatures of the semiconductor wafer.

In a further embodiment of the present invention, the different materials have different thicknesses.

It is advantageous here that the locally induced compensation stress can be optimally designed in an application-specific manner by the different thickness of the two materials.

In a development of the present invention, the material properties comprise a modulus of elasticity and a shrinkage behavior or a swelling behavior.

An advantage here is that the different curing behavior induces stresses and elongations into the semiconductor surface, so that the necessary compensation stresses can be adjusted exactly to the overall system.

In a development of the present invention, the different materials are arranged alternately relative to one another above certain mechanical stress regions vertically with respect to the front side.

In a further embodiment of the present invention, the different materials are arranged alternately relative to one another above certain mechanical stress regions in parallel with the front side.

In a development of the present invention, the different materials are arranged above certain mechanical stress regions in a point-like manner with respect to the front side.

It is advantageous here that the different alternating arrangement can specifically adjust the induced compressive or tensile stress locally with respect to their magnitude.

In a development of the present invention, the different materials can be printed.

An advantage here is that the materials can be applied in a simple manner.

In a further embodiment of the present invention, the semiconductor wafer comprises silicon, silicon carbide, sapphire, gallium nitride or QST.

A method according to an example embodiment of the present invention for processing a semiconductor wafer that has a front side and a rear side, wherein the front side is opposite the rear side, comprises ascertaining different mechanical stress regions on the front side of the semiconductor wafer and generating a structured carrier substrate on the front side of the semiconductor wafer, wherein different materials with different material properties are applied to the different stress regions by means of printing methods. The method further comprises grinding the rear side of the semiconductor wafer to a certain thickness, dividing the semiconductor wafer and detaching the structured carrier substrate from the front side of the semiconductor wafer.

An advantage here is that a very flat semiconductor wafer or a completely relaxed layer system is generated for the remaining processing of the semiconductor wafer, with which the internal mechanical stress or tension components of the semiconductor wafer can be compensated for in a narrow manner locally.

Further advantages can be found in the following description of exemplary embodiments of the present invention, and the rest of the disclosure herein.

### BRIEF DESCRIPTION OF THE DRAWINGS

The present invention is explained below with reference to preferred embodiments and the figures.

FIG. 1 is a plan view of a semiconductor wafer having different mechanical stress regions.

FIG. 2 shows an exemplary mechanical stress distribution on a surface of the semiconductor wafer.

FIG. 3A is a sectional view of the semiconductor wafer with a first exemplary embodiment of a structured carrier substrate, according to the present invention.

FIG. 3B is a sectional view of the semiconductor wafer with a second exemplary embodiment of the structured carrier substrate, according to the present invention.

FIG. 3C is a sectional view of the semiconductor wafer with a third exemplary embodiment of the structured carrier substrate, according to the present invention.

FIG. 4 shows a method for processing the semiconductor wafer, according to an example embodiment of the present invention.

### DETAILED DESCRIPTION OF EXAMPLE EMBODIMENTS

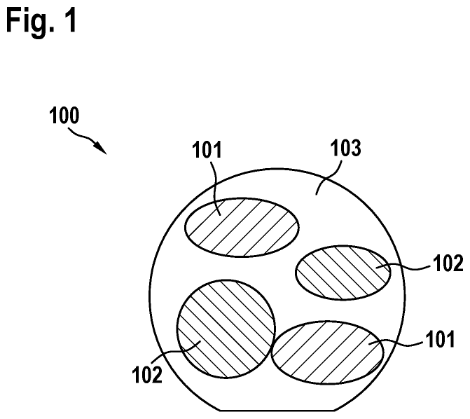

FIG. 1 is a plan view of a processed front side of a semiconductor wafer 100 with different mechanical stress regions. Mechanical stress regions that have a compressive stress 101, a tensile stress 102 or substantially a neutral mechanical stress 103, i.e. no mechanical stress, are shown.

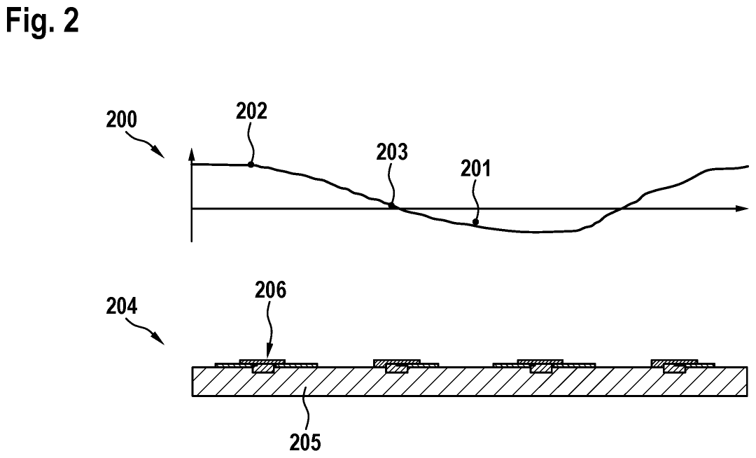

FIG. 2 shows an exemplary mechanical stress distribution 200 on a surface of the semiconductor wafer 205, wherein the surface represents a front side of the semiconductor wafer 205. The front side has active components 206 of power semiconductor devices. The stress distribution 200 is shown above a sectional view 204 of the semiconductor wafer 205. The location of the stress on the wafer is shown on the abscissa and the stress values are shown on the ordinate.

Values above the abscissa represent tensile stresses and values below the abscissa represent compressive stresses. Mechanical stress regions that have a compressive stress 201, a tensile stress 202 or substantially a neutral mechanical stress 203, i.e. no mechanical stress, are shown.

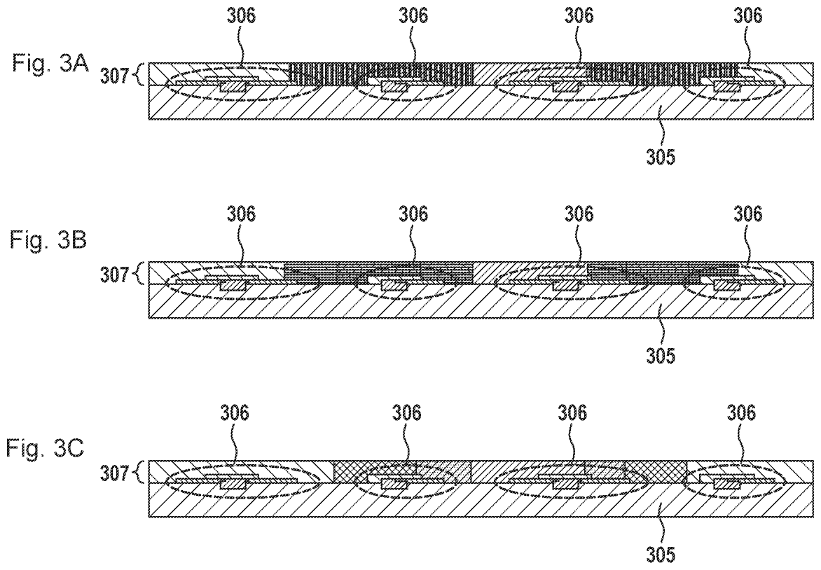

FIG. 3A is a sectional view through the semiconductor wafer 305 with a first exemplary embodiment of a structured carrier substrate 307. The front side of the semiconductor wafer 305 has active components 306 of power semiconductor devices, wherein the semiconductor wafer 305 has the same mechanical stress distribution as in FIG. 2. In the regions of the semiconductor wafer 305 in which a compressive stress prevails, a first material that induces a tensile stress in the semiconductor wafer or its surface is used, so that the compressive stress is compensated for or neutralized on the front side of the semiconductor wafer 305. The first material expands, for example, by UV curing or thermal curing or cross-linking, i.e. the volume of the material increases. When the first material cures, for example, small gas bubbles are formed that cause the material to swell. Alternatively, materials such as polyimide are used, which can absorb a certain medium such as water during an immersion process and swell as a result. In other words, the combination of shrinkage or expansion during curing and the modulus of elasticity generates the stress to be induced. The first material has a modulus of elasticity of between 0.5 and 4 MPa. The swelling of the first material has a value of less than 5%.

In the regions of the semiconductor wafer 305 in which a tensile stress prevails, a second material that induces a compressive stress in the semiconductor wafer or its surface is used, so that the tensile stress on the front side of the semiconductor wafer 305 is compensated for or neutralized. A compressive stress is introduced on the front side of the semiconductor wafer 305 if the second material shrinks during the UV curing or during the thermal curing or cross-linking. This means that the volume of the second material decreases. The second material comprises, for example, adhesives or inkjet materials and has a modulus of elasticity of between 0.5 and 4 MPa. The swelling of the second material has a value of less than 5%. Above certain mechanical stress regions, i.e. the neutral stress regions, a combination of the first material and the second material is arranged on the front side of the semiconductor wafer 305. The first material and the second material are arranged alternately relative to one another vertically with respect to the front side, i.e. the first material and the second material are arranged in strips vertically with respect to the surface of the semiconductor wafer 305. In other words, the first material and the second material vary horizontally with respect to the surface of the semiconductor wafer 305.

FIG. 3B is a sectional view through the semiconductor wafer 305 with a second exemplary embodiment of a structured carrier substrate 307. Identical reference signs denote the same features as in FIG. 3A. In this exemplary embodiment as well, the semiconductor wafer 305 has the same mechanical stress distribution as in FIG. 2. Above certain mechanical stress regions, i.e. the neutral stress regions, a combination of the first material and the second material is arranged on the front side of the semiconductor wafer 305. The first material and the second material are arranged alternately relative to one another in parallel with the front side, i.e. the first material and the second material are arranged in layers in parallel with the surface of the semiconductor wafer 304. In other words, the first material and the second material vary vertically with respect to the surface of the semiconductor wafer 304.

FIG. 3C is a sectional view through the semiconductor wafer 305 with a third exemplary embodiment of a structured carrier substrate 307. Identical reference signs denote the same features as in FIGS. 3A and 3B. In this exemplary embodiment as well, the semiconductor wafer 305 has the same mechanical stress distribution as in FIG. 2. Above certain mechanical stress regions, i.e. the neutral stress regions, a combination of the first material and the second material is arranged on the front side of the semiconductor wafer 305. The first material and the second material are arranged in a point-like manner with respect to the front side, i.e. the first material and the second material are arranged in voxels or drops with respect to the surface of the semiconductor wafer 305. In other words, the first material and the second material vary horizontally and vertically with respect to the surface of the semiconductor wafer 305.

The different materials are applied at the transitions of the respective different mechanical stress regions in such a way that the forces acting on the front side of the semiconductor wafer 305 compensate for one another. This means that the first material and the second material are arranged in a certain mixing ratio relative to one another. A certain amount of the first material and of the second material are applied, for example, on a 1 mm² area. When using an inkjet technology, this is controlled via the number of drops of the first material and the second material. For example, 20% of the first material and 80% of the second material can be applied to the specific mechanical stress region. The mixing ratio can be used to precisely set a value between 100% tensile stress and 100% compressive stress according to the local position on the semiconductor wafer 305.

In other words, the structured carrier substrate 307 comprises different materials with different material properties such as modulus of elasticity and shrinkage or swelling behavior, so that the different materials have different shrinkage and expansion behavior or stresses. Alternatively, materials that indeed have the same material properties, but comprise a different media concentration, can also be used. For this purpose, the different materials can have solvents. Thus, in both cases, there is a two-material or multi-material substrate.

In the different mechanical stress regions, the different materials can have different heights or thicknesses. Alternatively, the different materials can have the same thickness. The different materials are preferably printable, i.e. they can be applied with the aid of a printing method. The semiconductor wafer 305 comprises silicon, silicon carbide, sapphire, gallium nitride or QST, for example.

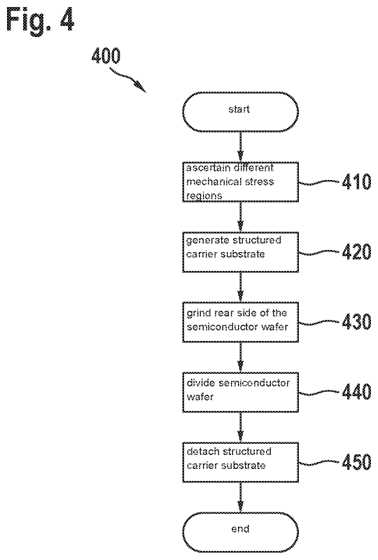

FIG. 4 shows a method 400 for processing a semiconductor wafer, wherein the semiconductor wafer has a front side and a rear side, wherein the front side is opposite the rear side. The method starts with step 410, in which different mechanical stress regions are ascertained on the front side of the semiconductor wafer. The ascertainment is effected, for example, by means of a simulation, a surface measurement or a laser measurement with which the curvatures or the distortions of the semiconductor wafer are detected. In a subsequent step 420, a structured carrier substrate is generated on the front side of the semiconductor wafer, wherein different materials are applied to the different stress regions. This is effected, for example, using printing methods such as inkjet technology or laser-induced forward transfer (LIFT). For example, a first material is applied to the front side of the semiconductor wafer, which locally induces a compressive stress, and a second material is applied to the front side of the semiconductor wafer, which locally induces a tensile stress. In the neutral stress regions, the first material and the second material are printed alternately. In other words, by locally applying different materials with different material properties, different stresses can be induced in the surface of the semiconductor wafer. In a subsequent step 430, the rear side of the semiconductor wafer is ground to a certain thickness. In a subsequent step 440, the semiconductor wafer is divided. This is effected, for example, with the aid of a sawing process or a laser process. In a subsequent step 450, the structured carrier substrate is detached from the front side of the semiconductor wafer. The steps 440 and 450 can also be interchanged in the order.

The method 400 can be used for processing or producing different power semiconductor devices such as MOSFETs, diodes, MEMS and IGBTs.

1-9. (canceled)

10. A semiconductor wafer having a front side and a rear side, wherein the front side is opposite the rear side, the front side has different mechanical stress regions, a structured carrier substrate that has different materials with different material properties is arranged on the front side, wherein the different materials are arranged on the different mechanical stress regions.

11. The semiconductor wafer according to claim 10, wherein the different materials have different thicknesses.

12. The semiconductor wafer according to claim 10, wherein the material properties include a modulus of elasticity and a shrinkage behavior or a swelling behavior.

13. The semiconductor wafer according to claim 10, wherein the different materials are arranged alternately relative to one another above certain of the mechanical stress regions vertically with respect to the front side.

14. The semiconductor wafer according to claim 10, wherein the different materials are arranged alternately relative to one another above certain of the mechanical stress regions in parallel with the front side.

15. The semiconductor wafer according to claim 10, wherein the different materials are arranged above certain of the mechanical stress regions in a point-like manner with respect to the front side.

16. The semiconductor wafer according to claim 10, wherein the different materials are printed.

17. The semiconductor wafer according to claim 10, wherein the semiconductor wafer includes silicon, or silicon carbide, or sapphire, or gallium nitride, or QST.

18. A method for processing a semiconductor wafer, wherein the semiconductor wafer has a front side and a rear side, wherein the front side is opposite the rear side, the method comprising the following steps:
ascertaining different mechanical stress regions on the front side of the semiconductor wafer;
generating a structured carrier substrate on the front side of the semiconductor wafer, wherein different materials with different material properties are applied to the different mechanical stress regions using printing methods;
grinding the rear side of the semiconductor wafer to a certain thickness;
dividing the semiconductor wafer; and
detaching the structured carrier substrate from the front side of the semiconductor wafer.
